(19) United States
(12) Patent Application Publication
(10) Pub. No.: US 2026/0045960 A1
(43) Pub. Date: Feb. 12, 2026

(54) TRANSMISSION SYSTEM, TRACKER CIRCUIT, AND AMPLIFICATION METHOD

(71) Applicant: Murata Manufacturing Co., Ltd., Nagaokakyo-shi (JP)

(72) Inventors: Muneharu KATO, Nagaokakyo-shi (JP); Sho OKAMOTO, Nagaokakyo-shi (JP); Kouji YAMAGUCHI, Nagaokakyo-shi (JP)

(21) Appl. No.: 19/360,206

(22) Filed: Oct. 16, 2025

Related U.S. Application Data
(63) Continuation of application No. PCT/JP2024/006928, filed on Feb. 27, 2024.

(30) Foreign Application Priority Data
Apr. 21, 2023 (JP) 2023-070374

(51) Int. Cl. H04B 1/04; G05F 1/46; H03F 3/24; H04B 1/18

(52) U.S. Cl. CPC H04B 1/0458; G05F 1/461; H03F 3/24; H04B 1/18; H03F 2200/102; H03F 2200/451; H04B 2001/0408

(57) ABSTRACT

A transmission system is provided that includes a radio-frequency integrated circuit configured to generate a first radio-frequency signal, a power amplifier configured to amplify the first radio-frequency signal, and a tracker circuit configured to selectively supply at least one voltage of a plurality of discrete voltages to the power amplifier. The tracker circuit is configured to receive the first radio-frequency signal generated by the radio-frequency integrated circuit and select the at least one voltage out of the plurality of discrete voltages.

### CROSS REFERENCE TO RELATED APPLICATIONS

This application is a continuation of International Application No. PCT/JP2024/006928, filed Feb. 27, 2024, which claims priority to Japanese Patent Application No. 2023-070374, filed Apr. 21, 2023, the contents of each of which are hereby incorporated by reference in their entireties.

### TECHNICAL FIELD

The present disclosure relates to a transmission system, a tracker circuit, and an amplification method.

### BACKGROUND

U.S. Pat. No. 9,041,464 discloses average power tracking (APT) that improves power efficiency by controlling a power supply voltage of a power amplifier in response to average output power. Moreover, U.S. Pat. No. 8,829,993 discloses digital envelope tracking (D-ET) for further improving power added efficiency.

However, in a transmission system disclosed in U.S. Pat. No. 8,829,993, a circuit generating a control signal for voltage selection is required to be incorporated in a radio frequency integrated circuit (RFIC). With the RFIC for the APT disclosed in U.S. Pat. No. 9,041,464, it is difficult to realize D-ET.

### SUMMARY OF THE INVENTION

In view of the foregoing, a transmission system, a tracker circuit, and an amplification method are provided that realize D-ET with a simple RFIC.

In an exemplary aspect, a transmission system is provided that includes a signal processing circuit configured to generate a first radio-frequency signal, a first power amplifier configured to amplify the first radio-frequency signal, and a tracker circuit configured to selectively supply at least one voltage of a plurality of discrete voltages to the first power amplifier. Moreover, the tracker circuit is configured to receive the first radio-frequency signal generated by the signal processing circuit and select the at least one voltage out of the plurality of discrete voltages.

In another exemplary aspect, a tracker circuit is provided that includes a voltage generation circuit configured to generate a plurality of discrete voltages, a power supply modulation circuit configured to selectively output at least one voltage of the plurality of discrete voltages to a power amplifier, a first external connection terminal through which a first control signal based on a serial data transmission standard is input, and a second external connection terminal through which a radio-frequency signal to be amplified by the power amplifier is input. The voltage generation circuit is controlled based on the first control signal, and the power supply modulation circuit is controlled based on the radio-frequency signal.

In yet another exemplary aspect, an amplification method is provided that includes generating a radio-frequency signal, generating a plurality of discrete voltages, detecting an envelope of the generated radio-frequency signal, selecting at least one voltage of the plurality of generated discrete voltages based on the detected envelope, and amplifying the radio-frequency signal by using the at least one selected voltage.

According to the exemplary aspects of the present disclosure, the D-ET is realized with the simple RFIC.

### BRIEF DESCRIPTION OF DRAWINGS

FIG. 1A is a graph illustrating an example of a transition of a power supply voltage in an APT mode.

FIG. 1B is a graph illustrating an example of a transition of the power supply voltage in an analog envelope tracking (A-ET) mode.

FIG. 1C is a graph illustrating an example of a transition of the power supply voltage in a D-ET mode.

FIG. 2 illustrates a circuit configuration of a communication device according to a first exemplary aspect of the present disclosure.

FIG. 3 illustrates circuit configurations of a pre-regulator circuit, a switched-capacitor circuit, and a power supply modulation circuit according to the first exemplary aspect of the present disclosure.

FIG. 4 illustrates circuit configurations of an envelope detector circuit, a control circuit, and a digital control circuit according to the first exemplary aspect of the present disclosure.

FIG. 5 is a flowchart illustrating an amplification method according to the first exemplary aspect of the present disclosure.

FIG. 6 illustrates arrangement of components in the communication device according to the first exemplary aspect of the present disclosure.

FIG. 7 illustrates a circuit configuration of a communication device according to a second exemplary aspect of the present disclosure.

FIG. 8 illustrates arrangement of components in the communication device according to the exemplary aspect of the present disclosure.

### DETAILED DESCRIPTION OF EMBODIMENTS

Hereinafter, exemplary embodiments of the present disclosure will be described in detail with reference to the drawings. Each of the embodiments to be described below indicates a comprehensive or specific example. Numeric values, shapes, materials, elements, arrangement of the elements, connection modes, and the like described in the following embodiments are exemplary and are not intended to limit the exemplary aspects of the present disclosure.

It is noted that each of the drawings is schematically illustrated by appropriately adjusting ratios, emphasizing, or omitting for illustrating the exemplary aspects of the present disclosure and is not necessarily precisely illustrated. The shapes, positional relationships, and ratios may be different from the actual shapes, positional relationships, and ratios. In each of the drawings, substantially the same elements are denoted by the same reference numerals, and duplicated description may be omitted or simplified.

In the drawings, the x axis and the y axis are perpendicular to each other in a plane parallel to a main surface of a mother board. Specifically, when the mother board has a rectangular shape in plan view, the x axis is parallel to the first edge of the mother board, and the y axis is parallel to the second edge of the mother board perpendicular to the first edge of the mother board. The z axis is perpendicular to the main surface of the mother board. The positive z direction is directed upward and the negative z direction is directed downward.

In the description below, the phrase “to be connected” includes not only to be directly connected through connecting terminals and/or wiring conductors but also to be electrically coupled via a different circuit element. Moreover, the phrase to be “directly connected” indicates direct connection through a connecting terminal and/or a wiring conductor without a circuit element interposed. For the phrase “C is connected between A and B”, one end of C is connected to A, and another end of C is connected to B. In this case, C is serially disposed on a path connecting A and B to each other. Moreover, the phrase “path connecting between A and B to each other” indicates a path including a conductor through which A is electrically connected to B.

In the description below, a “terminal” refers to a point where the conductor in an element ends. In an exemplary aspect, when the impedance of the conductor between elements is sufficiently low, the terminal is interpreted as not only a single point but also an arbitrary point on the conductor between the elements or the entirety of the conductor between the elements.

Furthermore, according to exemplary aspects, the terms representing the relationships between the elements such as “parallel”, “vertical”, and so forth, the terms representing the shapes of the elements such as “rectangular”, and ranges of values refer not only to exact meanings but also to substantially the same ranges, for example, errors of a few to several percents.

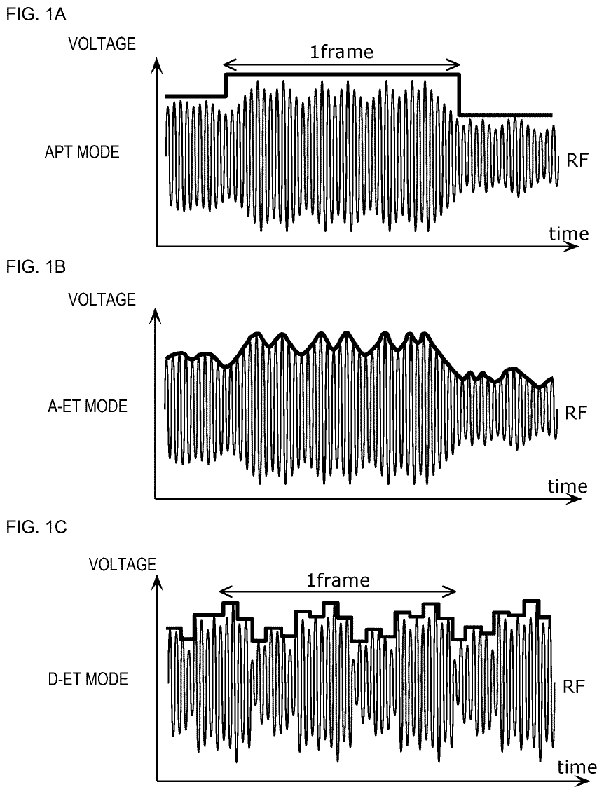

First, as a technique used to highly efficiently amplify radio-frequency signals, a tracking mode is described. In the tracking mode, a power supply voltage dynamically adjusted over time based on the radio-frequency signals is supplied to a power amplifier. In the tracking mode, the power supply voltage applied to the power amplifier is dynamically adjusted. There are several types of tracking modes. Herein, an APT mode, an A-ET mode, and a D-ET mode are described with reference to FIGS. 1A to 1C. In FIGS. 1A to 1C, the horizontal axis represents the time, and the vertical axis represents the voltage. A bold solid line represents the power supply voltage, and a thin solid line (e.g., a waveform) represent a modulating signal.

FIG. 1A is a graph illustrating an example of a transition of the power supply voltage in the APT mode. The APT mode is configured to cause the power supply voltage to vary to a plurality of discrete voltage levels on a frame-by-frame basis based on average power.

According to an exemplary aspect, a frame is a unit of a radio-frequency signal (e.g., modulating signal). For example, in 5GNR (5th generation new radio) and LTE (long term evolution), a frame includes ten sub-frames, each sub-frame includes a plurality of slots, and each slot includes a plurality of symbols. Moreover, the length of the sub-frame is 1 millisecond (ms), and the length of the frame is 10 ms.

The APT mode is configured to vary the voltage level by the frame or the greater length than the frame based on average power and is distinguished from a mode that causes the voltage level to vary by the smaller length than the frame (for example, by the sub-frames, slots, or symbols).

FIG. 1B is a graph illustrating an example of a transition of the power supply voltage in the A-ET mode. The A-ET mode is configured to continuously vary the power supply voltage based on an envelope signal. The A-ET mode allows the power supply voltage to track the envelope of the modulation signal.

The envelope signal indicates the envelope of the modulation signal. An envelope value is represented by, for example, a root of (I²+Q²). Here, (I, Q) represents a constellation point. The constellation point represents a digitally modulated signal in a constellation diagram. For example, (I, Q) is determined by a baseband integrated circuit (BBIC) based on transmission information.

FIG. 1C is a graph illustrating an example of a transition of the power supply voltage in the D-ET mode. The D-ET mode is configured to cause the power supply voltage to vary to a plurality of discrete voltage levels in a single frame based on the envelope signal. The D-ET mode allows the power supply voltage to track the envelope of the modulation signal. The D-ET causes the power supply voltage to vary at shorter time intervals than those of the APT.

### First Exemplary Embodiment

Hereinafter, a first exemplary embodiment of the present disclosure is described. A communication device 6 according to the present embodiment can be used to provide wireless connection. The communication device 6 can be implemented in user equipment (UE), for example, in a cellular network (also referred to as a mobile network) of mobile phones, smartphones, tablet computers, wearable devices, and the like. In another example, when the communication device 6 is implemented, wireless communication can be provided to Internet of things (IoT) sensor devices, medical/healthcare devices, vehicles, unmanned aerial vehicles (UAVs, so-called drones), and automated guided vehicles (AGVs). In yet another example, when the communication device 6 is implemented, wireless connection can be provided at a wireless access point or a wireless hotspot.

### 1.1 Circuit Configuration of Communication Device 6

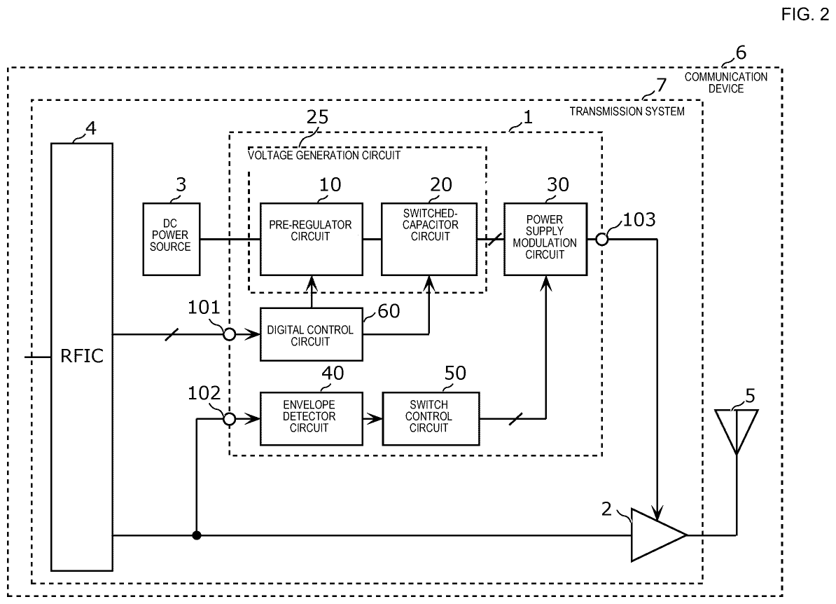

A circuit configuration of the communication device 6 according to the present embodiment is described with reference to FIG. 2. FIG. 2 illustrates a circuit configuration of the communication device 6 according to the present embodiment.

FIG. 2 illustrates an exemplary circuit configuration, and the communication device 6 can be implemented by using any of various circuit implementation and circuit techniques. Accordingly, description of the communication device 6 to be provided below is not to be understood as limiting.

The communication device 6 according to the present embodiment includes an antenna 5 and a transmission system 7. The transmission system 7 includes a tracker circuit 1, a power amplifier 2, a direct current (DC) power source 3, and a radio-frequency integrated circuit (RFIC) 4.

The tracker circuit 1 can be configured to selectively supply at least one voltage of the plurality of discrete voltages to the power amplifier 2. At this time, the tracker circuit 1 can receive a radio-frequency signal generated by the RFIC 4 and can select at least one voltage of the plurality of discrete voltages. Thus, the tracker circuit 1 can apply the D-ET mode to the power amplifier 2. The tracker circuit 1 can be configured to apply the APT mode to the power amplifier 2. A circuit configuration of the tracker circuit 1 will be described later.

According to an exemplary aspect, the power amplifier 2 is an example of a first power amplifier and connected between the RFIC 4 and the antenna 5 according to an exemplary aspect. The power amplifier 2 is also connected to the tracker circuit 1. The power amplifier 2 can amplify the radio-frequency signal supplied from the RFIC 4 by using the at least one of the plurality of discrete voltages selectively supplied from the tracker circuit 1.

The DC power source 3 can be configured to supply a DC voltage to the tracker circuit 1. For example, a rechargeable battery can be used as the DC power source 3. However, it is noted that this configuration is not limiting. The DC power source 3 may be omitted from the transmission system 7 or the communication device 6 in an alternative aspect.

The RFIC 4 is an example of a signal processing circuit configured to generate a radio-frequency signal (an example of a first radio-frequency signal) according to an exemplary aspect. The RFIC 4 can be configured to generate the radio-frequency signal by receiving a digital IQ signal from, for example, a BBIC (not illustrated) and performing a digital-to-analog conversion, quadrature modulation, upconverting, and the like on the digital IQ signal. Furthermore, the RFIC 4 can be configured to generate a digital control signal for controlling the tracker circuit 1. Part or the entirety of the functions of the RFIC 4 as a control unit may be implemented outside the RFIC 4 (for example, the tracker circuit 1) in exemplary aspects.

The antenna 5 can be configured to transmit the radio-frequency signal having been amplified by the power amplifier 2 to the outside. It is noted that the antenna 5 is not necessarily included in the communication device 6. Furthermore, the communication device 6 may include one or more antennas in addition to the antenna 5 in various exemplary aspects.

It is noted that the circuit configuration of the communication device 6 illustrated in FIG. 2 is exemplary and not limiting. For example, the communication device 6 may include a baseband signal processing circuit configured to perform signal processing by using a lower frequency band than the radio-frequency signal.

### 1.2 Circuit Configuration of Tracker Circuit 1

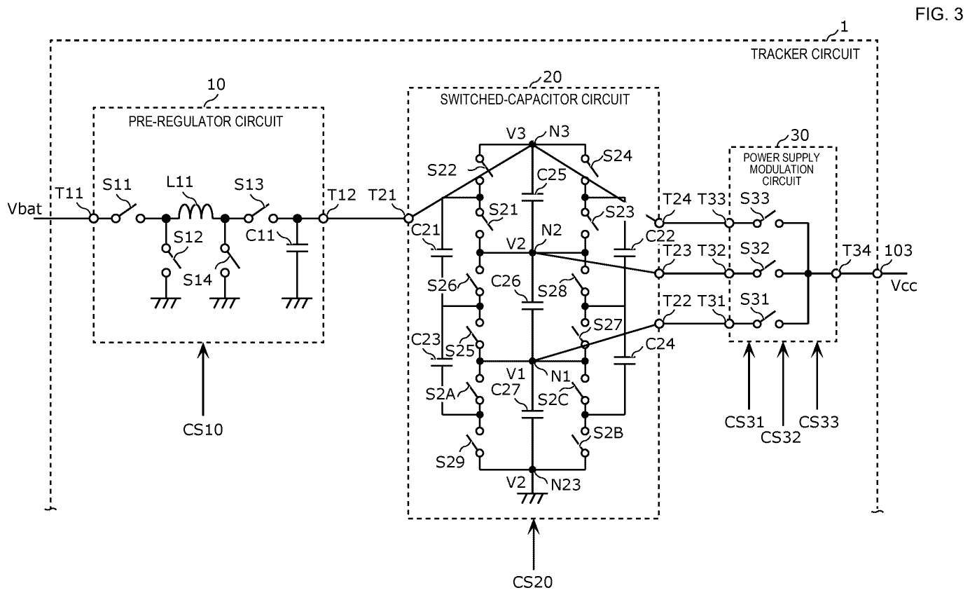

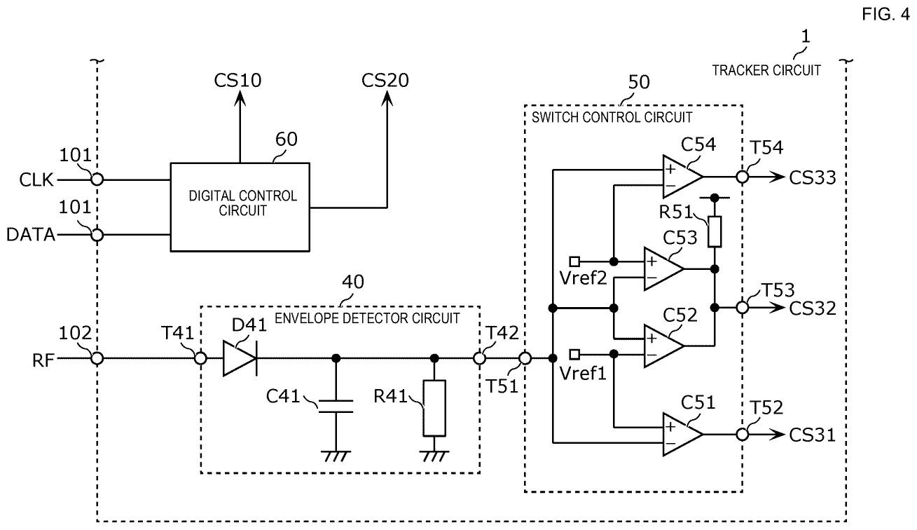

Next, the circuit configuration of the tracker circuit 1 is described with reference to FIGS. 2 to 4. FIG. 3 illustrates circuit configurations of a pre-regulator circuit 10, a switched-capacitor circuit 20, and a power supply modulation circuit 30 according to the present embodiment. FIG. 4 illustrates circuit configurations of an envelope detector circuit 40, a switch control circuit 50, and a digital control circuit 60 according to the present embodiment.

FIGS. 2 to 4 illustrate exemplary circuit configurations, and each of the tracker circuit 1, the pre-regulator circuit 10, the switched-capacitor circuit 20, the power supply modulation circuit 30, the envelope detector circuit 40, the switch control circuit 50, and the digital control circuit 60 can be implemented by using any of various circuit implementation and circuit techniques. Thus, the following description of the tracker circuit 1, the pre-regulator circuit 10, the switched-capacitor circuit 20, the power supply modulation circuit 30, the envelope detector circuit 40, the switch control circuit 50, and the digital control circuit 60 are not to be understood as limiting.

In the exemplary aspect, the tracker circuit 1 includes a voltage generation circuit 25 including the pre-regulator circuit 10 and the switched-capacitor circuit 20, the power supply modulation circuit 30, the envelope detector circuit 40, the switch control circuit 50, the digital control circuit 60 and external connection terminals 101 to 103.

The pre-regulator circuit 10 may also be referred to as a magnetic regulator or a DC/DC converter. According to the present embodiment, the pre-regulator circuit 10 is a buck-boost converter having a single input and a single output and can be configured to convert an input voltage (Vbat) from the DC power source 3 into an output voltage (adjustment voltage). The pre-regulator circuit 10 may be a buck converter or a boost converter. The pre-regulator circuit 10 can be configured to vary the output voltage based on, for example, the digital control signal from the RFIC 4. The circuit configuration of the pre-regulator circuit 10 will be described later with reference to FIG. 3.

The switched-capacitor circuit 20 can be configured to generate a plurality of discrete voltages based on the adjustment voltage supplied from the pre-regulator circuit 10. The circuit configuration of the switched-capacitor circuit 20 will be described later with reference to FIG. 3.

It is not necessarily the case that either the pre-regulator circuit 10 or the switched-capacitor circuit 20, or both, are included in the voltage generation circuit 25. For example, the pre-regulator circuit 10 may be disposed outside the voltage generation circuit 25 or the tracker circuit 1 in an exemplary aspect. Moreover, the voltage generation circuit 25 may include a plurality of pre-regulator circuits 10. In this case, the voltage generation circuit 25 does not include the switched-capacitor circuit 20.

The power supply modulation circuit 30 can be configured to selectively output at least one of the plurality of discrete voltages generated by the switched-capacitor circuit 20 to the power amplifier 2. That is, the power supply modulation circuit 30 can select at least one voltage out of the plurality of discrete voltages and supply the selected voltage to the power amplifier 2. The circuit configuration of the power supply modulation circuit 30 will be described later with reference to FIG. 3.

The envelope detector circuit 40 can receive the radio-frequency signal generated by the RFIC 4 and detect the envelope of the radio-frequency signal. The circuit configuration of the envelope detector circuit 40 will be described later with reference to FIG. 4.

The switch control circuit 50 can be configured to generate control signals CS31 to CS33 (examples of “second control signals”) for selecting the at least one voltage out of the plurality of discrete voltages based on the envelope detected by the envelope detector circuit 40. That is, the switch control circuit 50 can be configured to control the power supply modulation circuit 30 based on the radio-frequency signal from the RFIC 4. In other words, the power supply modulation circuit 30 is not controlled based on the digital control signal from the RFIC 4. The circuit configuration of the switch control circuit 50 will be described later with reference to FIG. 4.

The digital control circuit 60 can be configured to control the pre-regulator circuit 10 and the switched-capacitor circuit 20 based on a digital control signal from the RFIC 4 (example of the “first control signal”). Specifically, the digital control circuit 60 can be configured to generate control signals for controlling switches included in the pre-regulator circuit 10 and the switched-capacitor circuit 20 and output the generated signals. The digital control circuit 60 will be described later with reference to FIG. 4. The digital control circuit 60 is not necessarily included in the tracker circuit 1.

The external connection terminal 101 is an example of a first external connection terminal according to an exemplary aspect. The control signal (e.g., a first control signal) based on a serial data transmission standard is input through the external connection terminal 101. The external connection terminal 101 is externally connected to the RFIC 4 and internally connected to the digital control circuit 60. Although a control signal of, for example, a source-synchronous method or an embedded clock method can be used as the control signal based on the serial data transmission standard, this is not limiting.

The external connection terminal 102 is an example of a second external connection terminal according to an exemplary aspect. The radio-frequency signal to be amplified by the power amplifier 2 is input through the external connection terminal 102. The external connection terminal 102 is externally connected to the RFIC 4 and internally connected to the envelope detector circuit 40.

The external connection terminal 103 is an output terminal for supplying the power source voltage to the power amplifier 2. The external connection terminal 103 is externally connected to the power amplifier 2 and internally connected to the power supply modulation circuit 30.

### 1.2.1 Circuit Configuration of Pre-Regulator Circuit 10

Next, the circuit configuration of the pre-regulator circuit 10 included in the tracker circuit 1 is described with reference to FIGS. 2 to 3.

The pre-regulator circuit 10 includes an input terminal T11, an output terminal T12, switches S11 to S14, a power inductor L11, and a capacitor C11.

The input terminal T11 is a terminal for receiving the DC voltage (Vbat) from the DC power source 3. The input terminal T11 is externally connected to the DC power source 3 and internally connected to the switch S11.

The output terminal T12 is a terminal for supplying the adjustment voltage to the switched-capacitor circuit 20. The output terminal T12 is externally connected to an input terminal T21 of the switched-capacitor circuit 20 and internally connected to the switch S13.

The power inductor L11 is used to boost and buck the DC voltage (Vbat). One end of the power inductor L11 is connected to the switches S11 and S12, and another end of the power inductor L11 is connected to the switches S13 and S14.

The switch S11 is connected between the input terminal T11 and the one end of the power inductor L11. In this connecting structure, by switching the on/off state of the switch S11, the connection between the input terminal T11 and the one end of the power inductor L11 can be switched on or off.

The switch S12 is connected between the one end of the power inductor L11 and the ground. In this connecting structure, by switching the on/off state of the switch S12, the connection between the one end of the power inductor L11 and the ground can be switched on or off.

The switch S13 is connected between the other end of the power inductor L11 and the output terminal T12. In this connecting structure, by switching the on/off state of the switch S13, connection between the other end of the power inductor L11 and the output terminal T12 can be switched on or off.

The switch S14 is connected between the other end of the power inductor L11 and the ground. In this connecting structure, by switching the on/off state of the switch S14, connection between the other end of the power inductor L11 and the ground can be switched on or off.

The capacitor C11 is connected between the ground and a path between the switch S13 and the output terminal T12. Specifically, one electrode out of two electrodes of the capacitor C11 is connected to the switch S13 and the output terminal T12, and another electrode out of the two electrodes of the capacitor C11 is connected to the ground.

It is noted that the configuration of the pre-regulator circuit 10 illustrated in FIG. 3 is exemplary and is not to be in any way limiting. For example, a subset of the switches S11 to S14 may be replaced with a diode or diodes. Furthermore, part or the entirety of the pre-regulator circuit 10 is not necessarily included in the tracker circuit 1.

### 1.2.2 Circuit Configuration of Switched-Capacitor Circuit 20

Next, the circuit configuration of the switched-capacitor circuit 20 included in the tracker circuit 1 is described with reference to FIG. 3.

The switched-capacitor circuit 20 has a ladder-type circuit configuration. Specifically, the switched-capacitor circuit 20 includes capacitors C21 to C27, switches S21 to S2C, the input terminal T21, and output terminals T22 to T24. Energy and charges are input from the pre-regulator circuit 10 to a node N3 through the input terminal T21 and led to the power supply modulation circuit 30 from the nodes N1 to N3 through the output terminals T22 to T24.

The input terminal T21 is a terminal for receiving the adjustment voltage from the pre-regulator circuit 10. The input terminal T21 is externally connected to the pre-regulator circuit 10 and internally connected to the node N3.

The output terminal T22 is a terminal for supplying a voltage (V1) out of the plurality of discrete voltages to the power supply modulation circuit 30. The output terminal T22 is externally connected to the power supply modulation circuit 30 and internally connected to the node N1.

The output terminal T23 is a terminal for supplying a voltage (V2) out of the plurality of discrete voltages to the power supply modulation circuit 30. The output terminal T23 is externally connected to the power supply modulation circuit 30 and internally connected to the node N2.

The output terminal T24 is a terminal for supplying a voltage (V3) out of the plurality of discrete voltages to the power supply modulation circuit 30. The output terminal T24 is externally connected to the power supply modulation circuit 30 and internally connected to the node N3. The output terminal T24 may be integrated with the input terminal T21.

The capacitors C21 to C24 can be flying capacitors (also referred to as transfer capacitors) and are configured to boost and/or buck the adjustment voltage (V1) supplied from the pre-regulator circuit 10. More specifically, the capacitors C21 to C24 can be configured to transfer charges between the capacitors C21 to C24 and the nodes N1 to N3 and the ground so as to maintain V1 to V3 that satisfy (V3−V2):(V2−V1):(V1−VG)=1:1:1 and V3>V2>V1>VG at three nodes N1 to N3. Here, VG represents a ground potential.

One electrode out of two electrodes of the capacitor C21 is connected to one end of the switch S21 and one end of the switch S22. Another electrode out of the two electrodes of the capacitor C21 is connected to one end of the switch S25 and one end of the switch S26.

One electrode out of two electrodes of the capacitor C22 is connected to one end of the switch S23 and one end of the switch S24. Another electrode out of the two electrodes of the capacitor C22 is connected to one end of the switch S27 and one end of the switch S28.

One electrode out of two electrodes of the capacitor C23 is connected to the one end of the switch S25 and the one end of the switch S26. Another electrode out of the two electrodes of the capacitor C23 is connected to one end of the switch S29 and one end of the switch S2A.

One electrode out of two electrodes of the capacitor C24 is connected to the one end of the switch S27 and the one end of the switch S28. Another electrode out of the two electrodes of the capacitor C24 is connected to one end of the switch S2B and one end of the switch S2C.

The capacitors C25 to C27 can be smoothing capacitors that are configured to hold and smooth the voltages (V1 to V3) at the nodes N1 to N3.

The capacitor C25 is connected between the nodes N2 and N3. Specifically, one electrode out of two electrodes of the capacitor C25 is connected to the node N3. Another electrode out of the two electrodes of the capacitor C25 is connected to the node N2.

The capacitor C26 is connected between the nodes N1 and N2. Specifically, one electrode out of two electrodes of the capacitor C26 is connected to the node N2. Another electrode out of the two electrodes of the capacitor C26 is connected to the node N1.

The capacitor C27 is connected between the node N1 and the ground. Specifically, one electrode out of two electrodes of the capacitor C27 is connected to the node N1. Another electrode out of the two electrodes of the capacitor C27 is connected to the ground.

The switch S21 is connected between the capacitor C21 and the node N2. Specifically, the one end of the switch S21 is connected to the one electrode out of the two electrodes of the capacitor C21. Another end of the switch S21 is connected to the node N2.

The switch S22 is connected between the capacitor C21 and the node N3. Specifically, the one end of the switch S22 is connected to the one electrode out of the two electrodes of the capacitor C21. Another end of the switch S22 is connected to the node N3.

The switch S23 is connected between the capacitor C22 and the node N2. Specifically, the one end of the switch S23 is connected to the one electrode out of the two electrodes of the capacitor C22. Another end of the switch S23 is connected to the node N2.

The switch S24 is connected between the capacitor C22 and the node N3. Specifically, the one end of the switch S24 is connected to the one electrode out of the two electrodes of the capacitor C22. Another end of the switch S24 is connected to the node N3.

The switch S25 is connected between the capacitors C21 and C23 and the node N1. Specifically, the one end of the switch S25 is connected to the other electrode out of the two electrodes of the capacitor C21 and the one electrode out of the two electrodes of the capacitor C23. Another end of the switch S25 is connected to the node N1.

The switch S26 is connected between the capacitors C21 and C23 and the node N2. Specifically, the one end of the switch S26 is connected to the other electrode out of the two electrodes of the capacitor C21 and the one electrode out of the two electrodes of the capacitor C23. Another end of the switch S26 is connected to the node N2.

The switch S27 is connected between the capacitors C22 and C24 and the node N1. Specifically, the one end of the switch S27 is connected to the other electrode out of the two electrodes of the capacitor C22 and the one electrode out of the two electrodes of the capacitor C24. Another end of the switch S27 is connected to the node N1.

The switch S28 is connected between the capacitors C22 and C24 and the node N2. Specifically, the one end of the switch S28 is connected to the other electrode out of the two electrodes of the capacitor C22 and the one electrode out of the two electrodes of the capacitor C24. Another end of the switch S28 is connected to the node N2.

The switch S29 is connected between the capacitor C23 and the ground. Specifically, the one end of the switch S29 is connected to the other electrode out of the two electrodes of the capacitor C23. Another end of the switch S29 is connected to the ground.

The switch S2A is connected between the capacitor C23 and the node N1. Specifically, the one end of the switch S2A is connected to the other electrode out of the two electrodes of the capacitor C23. Another end of the switch S2A is connected to the node N1.

The switch S2B is connected between the capacitor C24 and the ground. Specifically, the one end of the switch S2B is connected to the other electrode out of the two electrodes of the capacitor C24. Another end of the switch S2B is connected to the ground.

The switch S2C is connected between the capacitor C24 and the node N1. Specifically, the one end of the switch S2C is connected to the other electrode out of the two electrodes of the capacitor C24. Another end of the switch S2C is connected to the node N1.

The on/off states of first set switches including the switches S22, S23, S26, S27, S2A, and S2B and second set switches including the switches S21, S24, S25, S28, S29, and S2C are switched to the opposite states based on a control signal CS20 from the digital control circuit 60.

Specifically, in a first phase, the switches of the first set are switched on and the switches of the second set are switched off. Thus, the one electrode out of the two electrodes of the capacitor C21 is connected to the node N3, the other electrode out of the two electrodes of the capacitor C21, the one electrode out of the two electrodes of the capacitor C22, and the one electrode out of the two electrodes of the capacitor C23 are connected to the node N2, the other electrode out of the two electrodes of the capacitor C22, the other electrode out of the two electrodes of the capacitor C23, and the one electrode out of the two electrodes of the capacitor C24 are connected to the node N3, and the other electrode out of the two electrodes of the capacitor C24 is connected to the ground.

Reversely, in a second phase, the switches of the first set are switched off and the switches of the second set are switched on. Thus, the one electrode out of the two electrodes of the capacitor C22 is connected to the node N3, the one electrode out of the two electrodes of the capacitor C21, the other electrode out of the two electrodes of the capacitor C22, and the one electrode out of the two electrodes of the capacitor C24 are connected to the node N2, the other electrode out of the two electrodes of the capacitor C21, the one electrode out of the two electrodes of the capacitor C23, and the other electrode out of the two electrodes of the capacitor C24 are connected to the node N3, and the other electrode out of the two electrodes of the capacitor C23 is connected to the ground.

According to an exemplary aspect, when the first phase and the second phase as described above are repeatedly performed, the capacitors C21 to C24 can be configured to charge and discharge complementarily. For example, in one of the first phase and the second phase, charging from the capacitors C21 and C23 to the capacitors C25 to C27 is executed, and in another of the first phase and the second phase, charging from the capacitors C22 and C24 to the capacitors C25 to C27 is executed. That is, the capacitors C25 to C27 are charged at all times from any of the capacitors C21 to C24, and accordingly, even when a current flows at high-speed from the node N1, N2, or N3 to the power supply modulation circuit 30, charges are replenished to the node N1, N2, or N3 at high-speed, and variation of the potential of the node N1, N2, or N3 is suppressed.

According to an exemplary aspect, when the switched-capacitor circuit 20 operates as described above, the switched-capacitor circuit 20 can maintain substantially the same voltages at both ends of each of the capacitors C25 to C27. Specifically, V1 to V3 that satisfy (V3−V2):(V2−V1):(V1−VG)=1:1:1 are maintained at three nodes N1 to N3 to which labels V1 to V3 are attached.

It is noted that the (V3−V2):(V2−V1):(V1−VG) are not limited to 1:1:1. This ratio can be arbitrarily designed (for example, 1:2:3, 1:2:4, 3:2:1, 4:2:1, or the like) according to various exemplary aspects.

### 1.2.3 Circuit Configuration of Power Supply Modulation Circuit 30

Next, the circuit configuration of the power supply modulation circuit 30 included in the tracker circuit 1 is described with reference to FIG. 3.

The power supply modulation circuit 30 includes input terminals T31 to T33, switches S31 to S33, and an output terminal T34.

The input terminals T31 to T33 are terminals for receiving the plurality of discrete voltages (V1 to V3) generated by the switched-capacitor circuit 20. The input terminals T31 to T33 are externally connected to the output terminals T22 to T24 of the switched-capacitor circuit 20, respectively, and internally connected to the switches S31 to S33, respectively.

The output terminal T34 is a terminal for selectively supplying at least one of the plurality of discrete voltages to the power amplifier 2. The output terminal T34 is externally connected to the power amplifier 2 and internally connected to the switches S31 to S33.

The switch S31 is connected between the input terminal T31 and the output terminal T34. In this connecting structure, by switching the on/off state of the switch S31 based on the control signal CS31 from the switch control circuit 50, the connection between the input terminal T31 and the output terminal T34 can be switched on or off.

The switch S32 is connected between the input terminal T32 and the output terminal T34. In this connecting structure, by switching the on/off state of the switch S32 based on the control signal CS32 from the switch control circuit 50, the connection between the input terminal T32 and the output terminal T34 can be switched on or off.

The switch S33 is connected between the input terminal T33 and the output terminal T34. In this connecting structure, by switching the on/off state of the switch S33 based on the control signal CS33 from the switch control circuit 50, the connection between the input terminal T33 and the output terminal T34 can be switched on or off.

According to the present embodiment, the switches S31 to S33 are controlled so as to be exclusively turned on. That is, the switches S31 to S33 are controlled such that only one of the switches S31 to S33 is switched on and all the other switches out of the switches S31 to S33 are switched off. Thus, the power supply modulation circuit 30 can supply a single voltage selected out of the plurality of discrete voltages (V1 to V3) to the power amplifier 2.

The configuration of the power supply modulation circuit 30 illustrated in FIG. 3 is exemplary and not limiting. In particular, as long as the switches S31 to S33 allow at least one of three input terminals T31 to T33 to be selectively connected to the output terminal T34, the switches S31 to S33 may be arranged and controlled in any manner. For example, two switches out of the switches S31 to S33 may be switched on and one switch out of the switches S31 to S33 may be switched off.

### 1.2.4 Circuit Configuration of Envelope Detector Circuit 40

Next, the circuit configuration of the envelope detector circuit 40 included in the tracker circuit 1 is described with reference to FIG. 4. The envelope detector circuit 40 includes an input terminal T41, an output terminal T42, a diode D41, a capacitor C41, and a resistor R41.

The input terminal T41 is a terminal for receiving a radio-frequency signal. The input terminal T41 is externally connected to the external connection terminal 102 and internally connected to an input end of the diode D41.

The output terminal T42 is a terminal for supplying the envelope signal to the switch control circuit 50. The output terminal T42 is externally connected to the switch control circuit 50 and internally connected to an output end of the diode D41.

The diode D41 is connected between the input terminal T41 and the output terminal T42.

The capacitor C41 is connected in parallel with the resistor R41 between the ground and a path between the output end of the diode D41 and the output terminal T42.

The resistor R41 is connected in parallel with the capacitor C41 between the ground and the path between the output end of the diode D41 and the output terminal T42.

FIG. 4 illustrates an example of the simplest circuit configuration of the envelope detector circuit 40.

However, the circuit configuration of the envelope detector circuit 40 is not limited to this.

### 1.2.5 Circuit Configuration of Switch Control Circuit 50

Next, the circuit configuration of the switch control circuit 50 included in the tracker circuit 1 is described with reference to FIG. 4.

The switch control circuit 50 includes an input terminal T51, output terminals T52 to T54, and comparators C51 to C54.

The input terminal T51 is a terminal for receiving the envelope signal. The input terminal T51 is externally connected to the envelope detector circuit 40 and internally connected to the comparators C51 to C54.

The output terminals T52 to T54 are terminals for respectively supplying the control signals CS31 to CS33 to the power supply modulation circuit 30. The output terminals T52 to T54 are connected to the power supply modulation circuit 30.

The control signals CS31 to CS33 are examples of a second control signal and are signals for selecting the at least one voltage out of the plurality of discrete voltages. Specifically, the control signals CS31 to CS33 are signals for respectively controlling the on/off state of the switches S31 to S33 of the power supply modulation circuit 30.

According to the present embodiment, the switch S31 is switched on when the control signal CS31 has a high-level voltage and the switch S31 is switched off when the control signal CS31 has a low-level voltage. Likewise, the switch S32 is switched on when the control signal CS32 has a high-level voltage and the switch S32 is switched off when the control signal CS32 has a low-level voltage. Likewise, the switch S33 is switched on when the control signal CS33 has a high-level voltage and the switch S33 is switched off when the control signal CS33 has a low-level voltage.

The relationships between the voltages of the control signals CS31 to CS33 and the on/off state of the switches S31 to S33 may be reversed. That is, the switch may be switched off when the control signal has a high-level voltage and the switch may be switched on when the control signal has a low-level voltage.

The comparator C51 can be configured to compare the envelope signal and a reference voltage Vref1 with each other. A noninverting input end of the comparator C51 is connected to a voltage source of the reference voltage Vref1. An inverting input end of the comparator C51 is connected to the input terminal T51. An output end of the comparator C51 is connected to the output terminal T52. Thus, when the reference voltage Vref1 is higher than the envelope signal, the comparator C51 can output the control signal CS31 through the output terminal T52 at a high-level voltage. In contrast, when the reference voltage Vref1 is lower than the envelope signal, the comparator C51 can output the control signal CS31 through the output terminal T52 at a low-level voltage.

The comparator C52 can compare the envelope signal and the reference voltage Vref1 with each other. A noninverting input end of the comparator C52 is connected to the input terminal T51. An inverting input end of the comparator C52 is connected to the voltage source of the reference voltage Vref1. An output end of the comparator C52 is connected to the output terminal T53.

The comparator C53 can be configured to compare the envelope signal and a reference voltage Vref2 with each other. A noninverting input end of the comparator C53 is connected to a voltage source of the reference voltage Vref2. An inverting input end of the comparator C53 is connected to the input terminal T51. An output end of the comparator C53 is connected to the output terminal T53. The reference voltage Vref2 is higher than the reference voltage Vref1.

The comparators C52 and C53 are included in a window comparator circuit. The window comparator circuit can output a high-level voltage through the output terminal T53 when the envelope signal is in a range of the reference voltage Vref1 and the reference voltage Vref2 and output a low-level voltage through the output terminal T53 when the envelope signal is out of the range of the reference voltage Vref1 and the reference voltage Vref2.

The comparator C54 can be configured to compare the envelope signal and the reference voltage Vref2 with each other. A noninverting input end of the comparator C54 is connected to the input terminal T51. An inverting input end of the comparator C54 is connected to the voltage source of the reference voltage Vref2. An output end of the comparator C54 is connected to the output terminal T54. Thus, the comparator C54 can output a high-level voltage through the output terminal T54 when the envelope signal is higher than the reference voltage Vref2 and output a low-level voltage through the output terminal T54 when the envelope signal is lower than the reference voltage Vref2.

As described above, the switch control circuit 50 can be configured to generate the control signal CS31 for selecting a first voltage (V1) out of the plurality of discrete voltages when the envelope signal is lower than the reference voltage Vref1. The switch control circuit 50 can also be configured to generate the control signal CS32 for selecting a second voltage (V2) out of the plurality of discrete voltages when the envelope signal is higher than the reference voltage Vref1 and lower than the reference voltage Vref2. The switch control circuit 50 can also be configured to generate the control signal CS33 for selecting a third voltage (V3) out of the plurality of discrete voltages when the envelope signal is higher than the reference voltage Vref2.

The circuit configuration of the switch control circuit 50 illustrated in FIG. 4 is exemplary and not limiting. For example, instead of the control signals CS31 to CS33, the switch control circuit 50 may output a digital control line (DCL) signal to the digital control circuit 60. In this case, the digital control circuit 60 can be configured to generate the control signals CS31 to CS33 of the switches S31 to S33 from the DCL signal.

### 1.2.6 Circuit Configuration of Digital Control Circuit 60

Next, the circuit configuration of the digital control circuit 60 included in the tracker circuit 1 is described with reference to FIG. 4.

The digital control circuit 60 can receive the digital control signal (the example of the “first control signal”) based on the serial data transmission standard through the external connection terminal 101. Referring to FIG. 4, a digital control signal of a source-synchronous method is used as the digital control signal based on the serial data transmission standard. Thus, the digital control circuit 60 can receive a clock signal (CLK) and a data signal (DATA) through two external connection terminals 101.

The digital control circuit 60 can process the clock signal (CLK) and the data signal (DATA) to generate control signals CS10 and CS20 for respectively controlling the pre-regulator circuit 10 and the switched-capacitor circuit 20. The on/off state of the switches S11 to S14 included in the pre-regulator circuit 10 is controlled by the control signal CS10, and the switches S21 to S2C included in the switched-capacitor circuit 20 are controlled by the control signal CS20.

### 1.3 Amplification Method

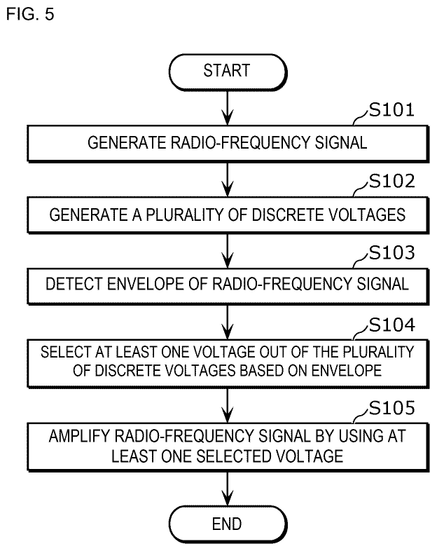

Next, an amplification method according to the present embodiment is described with reference to FIG. 5.

FIG. 5 is a flowchart illustrating the amplification method according to the present embodiment.

First, the RFIC 4 generates the radio-frequency signal (S101). The pre-regulator circuit 10 and the switched-capacitor circuit 20 generate the plurality of discrete voltages (V1 to V3, S102). The envelope detector circuit 40 detects the envelope of the radio-frequency signal generated by the RFIC 4 (S103). The power supply modulation circuit 30 is configured to select the at least one voltage out of the plurality of discrete voltages (V1 to V3) based on the envelope detected by the envelope detector circuit 40 (S104). The power amplifier 2 amplifies the radio-frequency signal generated by the RFIC 4 by using the at least one selected voltage (S105).

### 1.4 Example of Implementation of Communication Device 6

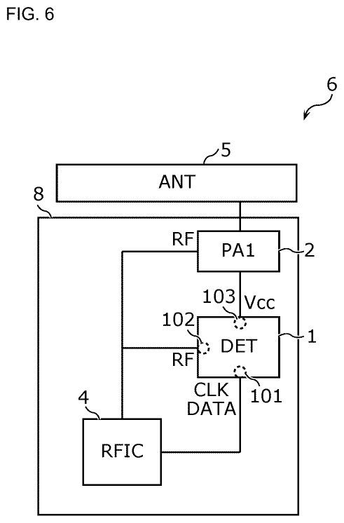

Next, an example of implementation of the communication device 6 is described with reference to FIG. 6. FIG. 6 illustrates arrangement of the components in the communication device 6 according to the present embodiment. Referring to FIG. 6, for ease of understanding of arrangement relationships between the components, abbreviation representing the functions of the components (for example, “ANT”) is attached to the components.

However, the abbreviation is not necessarily attached to the actual components. Also in FIG. 6, conductors electrically connecting the components are represented by simple lines.

A tracker module (DET), a PA module (PA1), and the RFIC 4 are disposed on a mother board 8.

The tracker circuit 1 is implemented in the tracker module (DET). The tracker module (DET) is disposed adjacent to the PA module (PA1) in plan view of the mother board 8.

The external connection terminal 101 of the tracker module (DET) is connected to the RFIC 4 so as to allow the clock signal (CLK) and the data signal (DATA) to be supplied from the RFIC 4 therethrough. The external connection terminal 102 of the tracker module (DET) is connected to the RFIC 4 so as to allow the radio-frequency signal (RF) to be supplied from the RFIC 4 therethrough. Here, the conductor connecting between the RFIC 4, and the tracker module (DET) branches off from the conductor connecting between the RFIC 4 and the PA module (PA1). The external connection terminal 103 of the tracker module (DET) is connected to the PA module (PA1) so as to allow the power supply voltage (Vcc) to be supplied therethrough.

The power amplifier 2 is implemented in the PA module (PA1). The PA module (PA1) is disposed near the antenna 5.

The antenna 5 (ANT) is disposed on the upper edge side of the mother board 8 near the PA module (PA1).

### 1.5 Technical Effects

As has been described, the transmission system 7 according to the present embodiment includes the RFIC 4 configured to generate the first radio-frequency signal, the power amplifier 2 configured to amplify the first radio-frequency signal, and the tracker circuit 1 configured to selectively supply at least one of the plurality of discrete voltages to the power amplifier 2. The tracker circuit 1 is configured to receive the first radio-frequency signal generated by the RFIC 4 and select the at least one voltage out of the plurality of discrete voltages.

Accordingly, the radio-frequency signal is received and the at least one voltage is selected out of the plurality of discrete voltages. Thus, it is not required for the RFIC 4 to generate the digital control signal for selecting the voltage. In the D-ET, the voltage is required to be switched at high-speed based on the envelope. Thus, it is difficult to control voltage selection by a digital control signal based on the ordinary serial data transmission standard. For this reason, in the related art, a digital control signal based on a parallel data transmission standard (for example, a digital control level signal) is used, and it is required that a circuit generating a digital control signal based on the parallel data transmission standard be incorporated into the RFIC 4. In contrast, in the transmission system 7 according to the present embodiment, the tracker circuit 1 receives the radio-frequency signal and selects the voltage. Thus, the circuit generating the digital control signal based on the parallel data transmission standard is not necessarily incorporated into the RFIC 4, and accordingly, the D-ET can be realized with the simple RFIC 4.

For example, in the transmission system 7 according to the present embodiment, the tracker circuit 1 may include the envelope detector circuit 40 configured to receive the first radio-frequency signal generated by the RFIC 4 and detect the envelope of the first radio-frequency signal, and the switch control circuit 50 configured to generate the control signal for selecting the at least one voltage out of the plurality of discrete voltages based on the envelope detected by the envelope detector circuit 40.

Accordingly, the voltage selection can be controlled based on the envelope detected by the envelope detector circuit 40, and the voltage can be switched at high-speed by using a comparatively simple circuit.

For example, in the transmission system 7 according to the present embodiment, the plurality of discrete voltages may include a first voltage and a second voltage higher than the first voltage. The switch control circuit 50 may be configured to generate the control signal for selecting the first voltage out of the plurality of discrete voltages when the envelope is lower than the reference voltage and generate the control signal for selecting the second voltage out of the plurality of discrete voltages when the envelope is higher than the reference voltage.

Accordingly, the control signal can be generated by comparing the envelope with the reference voltage. Thus, the control signal can be generated at high-speed by using a comparatively simple circuit such as a comparator.

For example, in the transmission system 7 according to the present embodiment, the switch control circuit 50 may be configured to generate the digital control level signal as the control signal.

Accordingly, instead of the RFIC 4, the switch control circuit 50 can be configured to generate the DCL signal. Thus, the digital control circuit configured to control voltage selection according to the DCL signal can also be utilized for the tracker circuit 1.

The tracker circuit 1 according to the present embodiment includes the voltage generation circuit 25 configured to generate the plurality of discrete voltages, the power supply modulation circuit 30 configured to selectively output at least one of the plurality of discrete voltages to the power amplifier 2, the external connection terminal 101 through which the first control signal (CLK, DATA) based on the serial data transmission standard are input, and the external connection terminal 102 through which the radio-frequency signal to be amplified by the power amplifier 2 is input. The voltage generation circuit 25 is controlled based on the first control signal, and the power supply modulation circuit 30 is controlled based on the radio-frequency signal.

Accordingly, the power supply modulation circuit 30 is controlled based on the radio-frequency signal. Thus, the tracker circuit 1 does not necessarily receive the digital control signal for voltage selection from the RFIC 4. Thus, the circuit generating the digital control signal based on the parallel data transmission standard is not necessarily incorporated into the RFIC 4, and accordingly, the D-ET can be realized with the simple RFIC 4.

For example, the tracker circuit 1 according to the present embodiment may further include the envelope detector circuit 40 configured to detect the envelope of the radio-frequency signal input through the external connection terminal 102, and the switch control circuit 50 configured to generate the second control signal (CS31 to CS33) for selecting the at least one voltage out of the plurality of discrete voltages based on the envelope detected by the envelope detector circuit 40.

Accordingly, the voltage selection can be controlled based on the envelope detected by the envelope detector circuit 40, and the voltage can be switched at high-speed by using a comparatively simple circuit.

For example, in the tracker circuit 1 according to the present embodiment, the switch control circuit 50 may include comparators C51 to C54 configured to compare the envelope with the reference voltage.

Accordingly, the switch control circuit 50 can be made by using comparatively simple circuits such as comparators C51 to C54.

For example, in the transmission system 7 according to the present embodiment, the switch control circuit 50 may be configured to generate the digital control level signal as the second control signal.

Accordingly, instead of the RFIC 4, the switch control circuit 50 can be configured to generate the DCL signal. Thus, the digital control circuit configured to control voltage selection according to the DCL signal can also be utilized for the tracker circuit 1.

The amplification method according to the present embodiment includes generating the radio-frequency signal (S101), generating the plurality of discrete voltages (S102), detecting the envelope of the generated radio-frequency signal (S103), selecting the at least one voltage out of the plurality of generated discrete voltages based on the detected envelope (S104), and amplifying the radio-frequency signal by using the at least one selected voltage (S105).

Accordingly, the envelope is detected from the radio-frequency signal and the voltage is selected based on the envelope. Thus, the RFIC 4 does not necessarily generate the digital control signal for voltage selection.

Thus, the circuit generating the digital control signal based on the parallel data transmission standard is not necessarily incorporated into the RFIC 4, and accordingly, the D-ET can be realized with the simple RFIC 4.

### Second Exemplary Embodiment

Next, a second exemplary embodiment of the present disclosure is described. The main difference between the second exemplary embodiment and the first exemplary embodiment is that, in the second embodiment, the communication device includes a power amplifier to which the APT mode is applied, but the D-ET mode is not. Hereinafter, the present embodiment is described with reference to the drawings by focusing on the difference from the first exemplary embodiment.

### 2.1 Circuit Configuration of Communication Device 6A

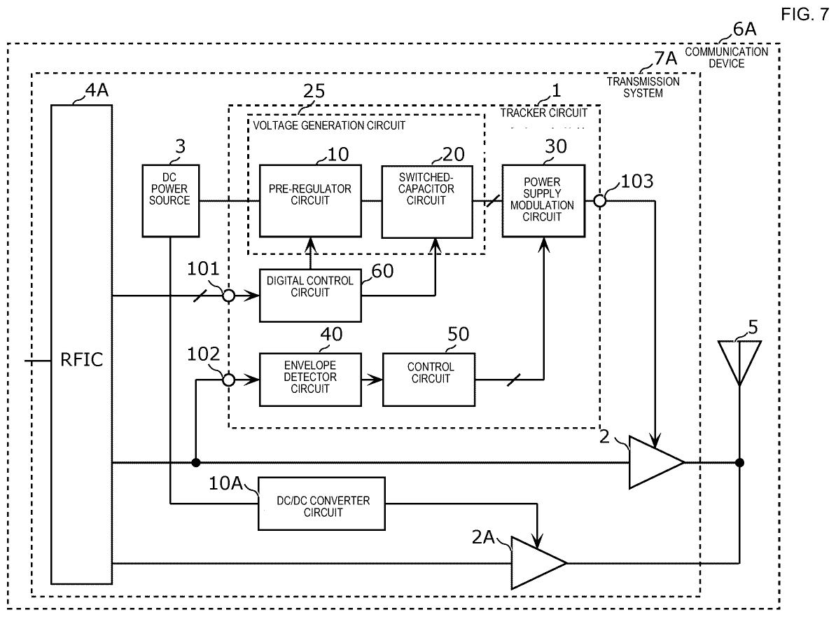

A circuit configuration of a communication device 6A according to the present embodiment is described with reference to FIG. 7. FIG. 7 illustrates a circuit configuration of the communication device 6A according to the present embodiment.

FIG. 7 illustrates an exemplary circuit configuration, and the communication device 6A can be implemented by using any of various circuit implementation and circuit techniques. Accordingly, description of the communication device 6A to be provided below is not to be limiting in any way.

The communication device 6A according to the present embodiment includes a transmission system 7A and the antenna 5. The transmission system 7A includes the tracker circuit 1, the power amplifier 2, the DC power source 3, an RFIC 4A, a DC/DC converter circuit 10A, and a power amplifier 2A.

The RFIC 4A can be configured to generate a second radio-frequency signal supplied to the power amplifier 2A in addition to the first radio-frequency signal supplied to the power amplifier 2.

The DC/DC converter circuit 10A can be configured to convert the input voltage (Vbat) from the DC power source 3 into a supply voltage (Vcc) to the power amplifier 2A. The DC/DC converter circuit 10A can vary the supply voltage (Vcc) to the power amplifier 2A based on average power of the second radio-frequency signal supplied to the power amplifier 2A. Thus, the DC/DC converter circuit 10A can be configured to apply the APT mode to the power amplifier 2A. The DC/DC converter circuit 10A has a circuit configuration similar to or the same as the circuit configuration of the pre-regulator circuit 10. Thus, illustration and description of the DC/DC converter circuit 10A are omitted.

The power amplifier 2A is connected between the RFIC 4A and the antenna 5. Furthermore, the power amplifier 2A is connected to the DC/DC converter circuit 10A. The power amplifier 2A can amplify the second radio-frequency signal supplied from the RFIC 4A by using a voltage supplied from the DC/DC converter circuit 10A.

### 2.2 Example of Implementation of Communication Device 6A

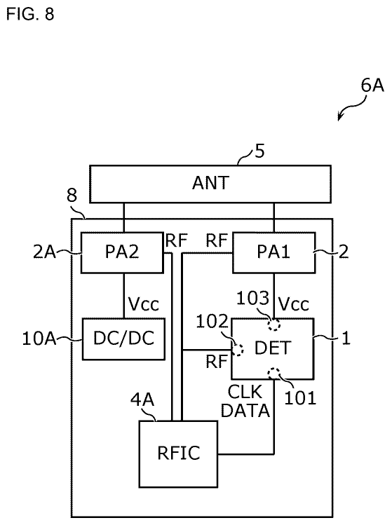

Next, an example of implementation of the communication device 6A is described with reference to FIG. 8. FIG. 8 illustrates arrangement of the components in the communication device 6A according to the present embodiment. Referring to FIG. 8, for ease of understanding of arrangement relationships between the components, abbreviation representing the functions of the components (for example, “ANT”) is attached to the components. However, the abbreviation is not necessarily attached to the actual components. Also in FIG. 8, conductors electrically connecting the components are represented by simple lines.

The tracker module (DET), the PA module (PA1, PA2), the RFIC 4A, and a converter module (DC/DC) are disposed on the mother board 8.

The DC/DC converter circuit 10A is implemented in the converter module (DC/DC). The converter module (DC/DC) is disposed adjacent to the PA module (PA2) in plan view of the mother board 8.

The power amplifier 2A is implemented in the PA module (PA2). The PA module (PA2) is disposed close to the antenna 5.

### 2.3 Technical Effects

As has been described, in the transmission system 7A according to the present embodiment, the RFIC 4A may be configured to further generate the second radio-frequency signal. The transmission system 7A may further include the DC/DC converter circuit 10A configured to convert the input voltage into the supply voltage, and the power amplifier 2A configured to amplify the second radio-frequency signal by using the supply voltage from the DC/DC converter circuit 10A.

Accordingly, the D-ET and the APT can be realized with the simple RFIC 4A.

### Additional Exemplary Embodiments

Although the transmission system, the tracker circuit, and the amplification method according to the exemplary aspects has been described above based on the embodiments, the transmission system, the tracker circuit, or the amplification method described herein is not limited to the above-described embodiments. The exemplary aspects can also include other embodiments realized by combining arbitrary elements in the above-described embodiments, modifications obtained by making various changes, to the above-described embodiments, conceived by a person skilled in the art without departing from the gist of the present disclosure, and various apparatuses into which the above-described transmission system or the above-described tracker circuit is incorporated.

For example, in the circuit configurations of the various circuits according to the above-described embodiments, other circuit elements and wiring may be inserted between the paths connecting the circuit elements and signal paths disclosed in the drawings. For example, a filter and/or an impedance matching circuit may be inserted between the power amplifier 2 and the antenna 5 in an exemplary aspect.

For example, in the above-described embodiments, the number of the plurality of discrete voltages generated by the switched-capacitor circuit 20 may be two or may be four or more. In this case, the number of rungs of the ladder of the switched-capacitor circuit 20 may be increased.

For example, the tracker circuit 1 may be configured to supply the voltage to a plurality of power amplifiers. In this case, the tracker circuit 1 may include a plurality of power supply modulation circuits 30 in an exemplary aspect.

The exemplary aspects of the present disclosure can be widely utilized in communication equipment such as mobile phones as a transmission system to transmit radio-frequency signals.

### REFERENCE SIGNS LIST

1 tracker circuit
2, 2A power amplifier
3 DC power source
4, 4A RFIC
5 antenna
6, 6A communication device
7, 7A transmission system
8 mother board
10 pre-regulator circuit
10A DC/DC converter circuit
20 switched-capacitor circuit
25 voltage generation circuit
30 power supply modulation circuit
40 envelope detector circuit
50 switch control circuit
60 digital control circuit
101, 102, 103 external connection terminal

1. A transmission system comprising:
a signal processing circuit configured to generate a first radio-frequency signal;
a first power amplifier configured to amplify the first radio-frequency signal; and
a tracker circuit configured to selectively supply at least one voltage of a plurality of discrete voltages to the first power amplifier,
wherein the tracker circuit is configured to receive the first radio-frequency signal generated by the signal processing circuit and to select the at least one voltage from the plurality of discrete voltages.

2. The transmission system according to claim 1, wherein the tracker circuit includes an envelope detector circuit configured to receive the first radio-frequency signal generated by the signal processing circuit and to detect an envelope of the first radio-frequency signal.

3. The transmission system according to claim 2, wherein the tracker circuit further includes a switch control circuit configured to generate a control signal for selecting the at least one voltage based on the envelope detected by the envelope detector circuit.

4. The transmission system according to claim 3, wherein the plurality of discrete voltages include a first voltage and a second voltage higher than the first voltage.

5. The transmission system according to claim 4, wherein the switch control circuit is configured to:
generate the control signal for selecting the first voltage from the plurality of discrete voltages when the envelope is lower than a reference voltage, and
generate the control signal for selecting the second voltage from the plurality of discrete voltages when the envelope is higher than the reference voltage.

6. The transmission system according to claim 3, wherein the switch control circuit is configured to generate a digital control level signal as the control signal.

7. The transmission system according to claim 5, wherein the switch control circuit is configured to generate a digital control level signal as the control signal.

8. The transmission system according to claim 1, wherein:
the signal processing circuit is configured to further generate a second radio-frequency signal, and
the transmission system further includes:
a converter circuit configured to convert an input voltage into a supply voltage, and
a second power amplifier configured to amplify the second radio-frequency signal based on the supply voltage from the converter circuit.

9. A tracker circuit comprising:
a voltage generation circuit configured to generate a plurality of discrete voltages;
a power supply modulation circuit configured to selectively output at least one voltage from the plurality of discrete voltages to a power amplifier;
a first external connection terminal configured to receive a first control signal based on a serial data transmission standard; and
a second external connection terminal configured to receive a radio-frequency signal to be amplified by the power amplifier,
wherein the voltage generation circuit is controlled based on the first control signal, and the power supply modulation circuit is controlled based on the radio-frequency signal.

10. The tracker circuit according to claim 9, further comprising:
an envelope detector circuit configured to detect an envelope of the radio-frequency signal received by the second external connection terminal; and
a switch control circuit configured to generate a second control signal for selecting the at least one voltage based on the envelope detected by the envelope detector circuit.

11. The tracker circuit according to claim 10, wherein the switch control circuit includes a comparator configured to compare the envelope with a reference voltage.

12. The tracker circuit according to claim 10, wherein the switch control circuit is configured to generate a digital control level signal as the second control signal.

13. An amplification method comprising:
generating a radio-frequency signal;
generating a plurality of discrete voltages;
detecting an envelope of the generated radio-frequency signal;
selecting at least one voltage from the plurality of generated discrete voltages based on the detected envelope; and
amplifying the radio-frequency signal based on the at least one selected voltage.

14. The amplification method according to claim 13, further comprising generating a control signal for selecting the at least one voltage based on the envelope detected.

15. The amplification method according to claim 14, wherein the plurality of discrete voltages include a first voltage and a second voltage higher than the first voltage.

16. The amplification method according to claim 15, further comprising:
generating the control signal for selecting the first voltage from the plurality of discrete voltages when the envelope is lower than a reference voltage, and
generating the control signal for selecting the second voltage from the plurality of discrete voltages when the envelope is higher than the reference voltage.

17. The amplification method according to claim 14, further comprising generating a digital control level signal as the control signal.

18. The amplification method according to claim 13, further comprising:
generating an additional radio-frequency signal;
converting an input voltage into a supply voltage; and
amplifying the additional radio-frequency signal based on the supply voltage.
